(19) United States
(12) Patent Application Publication
(10) Pub. No.: US 2026/0090394 A1
(43) Pub. Date: Mar. 26, 2026

(54) SEMICONDUCTOR PACKAGE AND METHOD OF MANUFACTURING THE SAME

(71) Applicant: Samsung Electronics Co., Ltd., Suwon-si (KR)

(72) Inventor: Choongjae Lee, Suwon-si (KR)

(21) Appl. No.: 19/313,143

(22) Filed: Aug. 28, 2025

(30) Foreign Application Priority Data
Sep. 24, 2024 (KR) 10-2024-0128893

(51) Int. Cl. H01L 23/64; H01L 21/48; H01L 23/00; H01L 23/498; H01L 23/538; H01L 25/16; H01L 25/18; H10B 80/00; H10D 80/30

(52) U.S. Cl. CPC H10W 44/501; H10W 70/05; H10W 70/093; H10W 70/095; H10W 70/611; H10W 70/65; H10W 90/00; H10W 90/401; H10W 90/701; H10B 80/00; H10D 80/30; H10W 74/15; H10W 90/724; H10W 90/734

(57) ABSTRACT

A semiconductor package includes a redistribution substrate including a first insulating layer, redistribution patterns on the first insulating layer, and redistribution vias extending through the first insulating layer and electrically connected to a first redistribution pattern and a second redistribution via electrically connected to a second redistribution pattern. A semiconductor chip is on the redistribution substrate and electrically connected to the redistribution patterns. A rigid structure is on the redistribution substrate and has a through-hole with a passive device. The rigid structure includes a second insulating layer, a lower pad; an upper pad; a through-via extending through the second insulating layer and connecting the lower pad and the upper pad; and the passive device. The passive device has a connection terminal in contact with the second redistribution via, and the first and second insulating layers include different insulating materials.

### CROSS-REFERENCE TO RELATED APPLICATION(S)

This application claims benefit of priority to Korean Patent Application No. 10-2024-0128893 filed on Sep. 24, 2024, in the Korean Intellectual Property Office, the disclosure of which is incorporated herein by reference in its entirety.

### BACKGROUND

As electronic devices become lighter and higher performance, the development of miniaturized and high-performance semiconductor packages is also required in a semiconductor package field. In order to realize miniaturization and high-performance of semiconductor packages, research and development of semiconductor packages including interposer substrates with passive devices embedded therein have been continuously conducted.

### SUMMARY

An aspect of the present disclosure is to provide a semiconductor package including an interposer substrate with a passive device embedded therein and a method of manufacturing the same.

As a solving means of the above-described aspect, some example implementations of the present disclosure provides a semiconductor package including: a redistribution substrate having a first surface and a second surface opposite to the first surface, the redistribution substrate comprising a first insulating layer, redistribution patterns disposed on the first insulating layer and comprising first and second redistribution patterns, and redistribution vias comprising a first redistribution and a second redistribution via, the first redistribution viaextending through the first insulating layer and electrically connected to the first redistribution pattern and the second redistribution via being electrically connected to the second redistribution pattern; a semiconductor chip on the first surface of the redistribution substrate, the semiconductor chip being electrically connected to the redistribution patterns; a rigid structure on the second surface of the redistribution substrate, the rigid structure having a through-hole, wherein the rigid structure comprises: a second insulating layer; a lower pad at a lower portion of the second insulating layer; an upper pad at an upper portion of the second insulating layer and electrically connected to the first redistribution via; a through-via extending through the second insulating layer and connecting the lower pad and the upper pad; and a passive device within the through-hole of the rigid structure, the passive device having a connection terminal in contact with the second redistribution via, and wherein the first insulating layer and the second insulating layer comprise different insulating materials from each other.

Additionally, provided is a semiconductor package including: a core structure comprising a core substrate and build-up layers stacked on each of an upper portion and a lower portion of the core substrate, the core structure having a first front pad on a front surface thereof; an interposer substrate comprising a redistribution substrate on the core structure and having a first surface and a second surface opposite to the first surface, and a rigid structure on the second surface and having a through-hole, wherein the redistribution substrate comprises a first insulating layer, redistribution patterns disposed on the first insulating layer and comprising first and second redistribution patterns, and redistribution vias comprising a first redistribution via extending through the first insulating layer and electrically connected to the first redistribution pattern and a second redistribution via electrically connected to the second redistribution pattern, and the rigid structure comprises a second insulating layer, a lower pad disposed at a lower portion of the second insulating layer, an upper pad disposed on an upper portion of the second insulating layer and electrically connected to the first redistribution pattern, and a through-via extending through the second insulating layer and connecting the lower and upper pads; at least one first semiconductor chip on the first surface of the redistribution substrate, the at least one first semiconductor chip being electrically connected to the redistribution patterns; a passive device within the through-hole of the rigid structure, and the passive device comprising a first active surface and a connection terminal disposed on the first active surface and contacting the second redistribution via; and a connection bump between the core structure and the rigid structure of the interposer substrate, the connection bump electrically connecting the first front pad of the core structure and the lower pad of the rigid structure, wherein the first insulating layer and the second insulating layer comprise different insulating materials from each other.

Additionally, provided is a semiconductor package including: a core structure comprising a core substrate and build-up layers stacked on an upper portion and a lower portion of the core substrate, the core structure having a front pad on a front surface thereof; an interposer substrate comprising a redistribution substrate disposed on the core structure and having a first surface and a second surface opposite to the first surface, and a rigid structure on the second surface and having a through-hole, wherein the redistribution substrate comprises: a first insulating layer; redistribution patterns on the first insulating layer and including first to third redistribution patterns; and redistribution vias comprising a first redistribution via extending through the first insulating layer and electrically connected to the first redistribution pattern and a second redistribution via electrically connected to the second redistribution pattern, and wherein the rigid structure comprises: a second insulating layer; a lower pad at a lower portion of the second insulating layer; an upper pad on an upper portion of the second insulating layer and electrically connected to the first redistribution pattern; and a through-via extending through the second insulating layer and connecting the lower pad and the upper pad; at least one first semiconductor chip on the first surface of the redistribution substrate, the at least one first semiconductor chip being electrically connected to the first and second redistribution patterns; a second semiconductor chip on the first surface of the redistribution substrate, the second semiconductor chip being electrically connected to the at least one first semiconductor chip by the third redistribution pattern; a passive component within the through-hole of the rigid structure, the passive component being electrically connected to the at least one first semiconductor chip by the second redistribution pattern; and a connection bump between the core structure and the rigid structure of the interposer substrate, the connection bump electrically connecting the front pad of the core structure and the lower pad of the rigid structure, wherein the through-via and the passive component are in parallel with each other, and a width of the through-via in a horizontal direction becomes narrower as the through-via approaches the lower pad.

According to example implementations of the technical concept of the present disclosure, provided are a semiconductor package including an interposer substrate with a passive device embedded therein and a method of manufacturing the same.

Specifically, according to the present disclosure, in a semiconductor package having an interposer substrate having a rigid structure and a redistribution substrate, a semiconductor package having improved Power Integrity (PI) characteristics may be provided by embedding passive devices in a rigid structure.

Advantages and effects of the present application are not limited to the foregoing content and may be more easily understood in the process of describing some specific example implementations of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor package according to some example implementations;

FIG. 2A is a cross-sectional view of a semiconductor package taken along line I-I′ of FIG. 1;

FIG. 2B is a partially enlarged view of a semiconductor package according to some example implementations;

FIG. 3 is a partially enlarged view of a semiconductor package according to some example implementations;

FIG. 4 is a partially enlarged view of a semiconductor package according to some example implementations;

FIG. 5A is a cross-sectional view of a semiconductor package taken along line I-I′ of FIG. 1;

FIG. 5B is a partially enlarged view of a semiconductor package according to some example implementations;

FIG. 6 is a partially enlarged view of a semiconductor package according to some example implementations;

FIG. 7 is a partially enlarged view of a semiconductor package according to some example implementations;

FIG. 8 is a partially enlarged view of a semiconductor package according to some example implementations;

FIGS. 9A to 9H are cross-sectional views illustrating a process order for describing a method of manufacturing a semiconductor package according to some example implementations;

FIGS. 10A to 10F are cross-sectional views illustrating a method of manufacturing a semiconductor package according to some example implementations according to the process order; and

FIG. 11 is a cross-sectional view illustrating a method of manufacturing a semiconductor package according to some example implementations according to the process order.

### DETAILED DESCRIPTION

Hereinafter, the terms ‘above,’ ‘upper portion,’ ‘upper surface,’ ‘below’, ‘lower portion,’ ‘lower surface,’ ‘side surface,’ ‘upper end,’ ‘lower end,’ and the like, may be understood as being indicated based on the drawing, except that they are indicated by drawing references and referred to separately. The terms “upper,” “intermediate,” “lower”, and the like, may be replaced with other terms, such as “first,” “second,” and “third,” and used to describe components of the specification. The terms “first,” “second,” and “third” may be used to describe various components, but the components are not limited by the terms, and the “first component” may be named as the “second component.”

Hereinafter, example implementations of the present disclosure will be described with reference to the accompanying drawings.

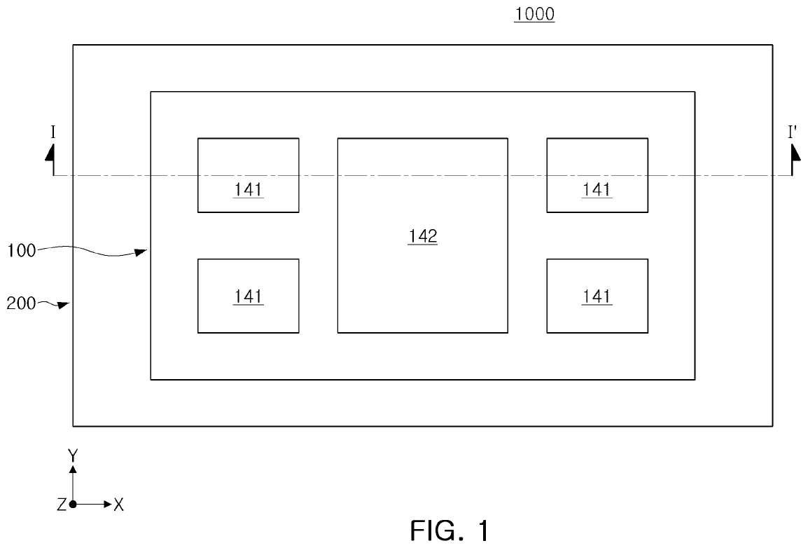

FIG. 1 is a plan view illustrating a semiconductor package according to some example implementations.

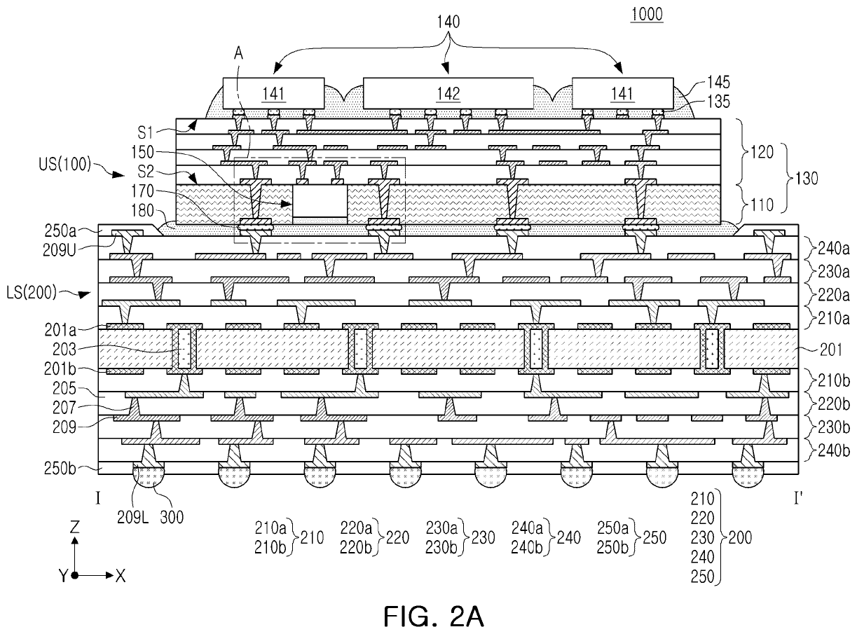

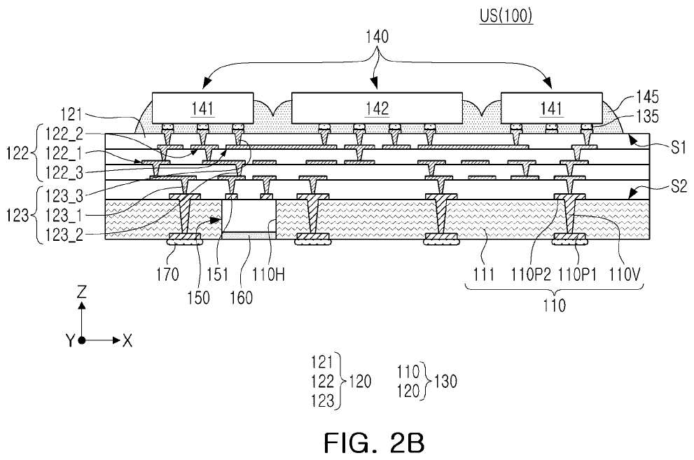

FIG. 2A is a cross-sectional view of a semiconductor package taken along line I-I′ of FIG. 1.

FIG. 2B is a partially enlarged view of a semiconductor package according to some example implementations. FIG. 2B is a partially enlarged view illustrating an upper structure US of FIG. 2A.

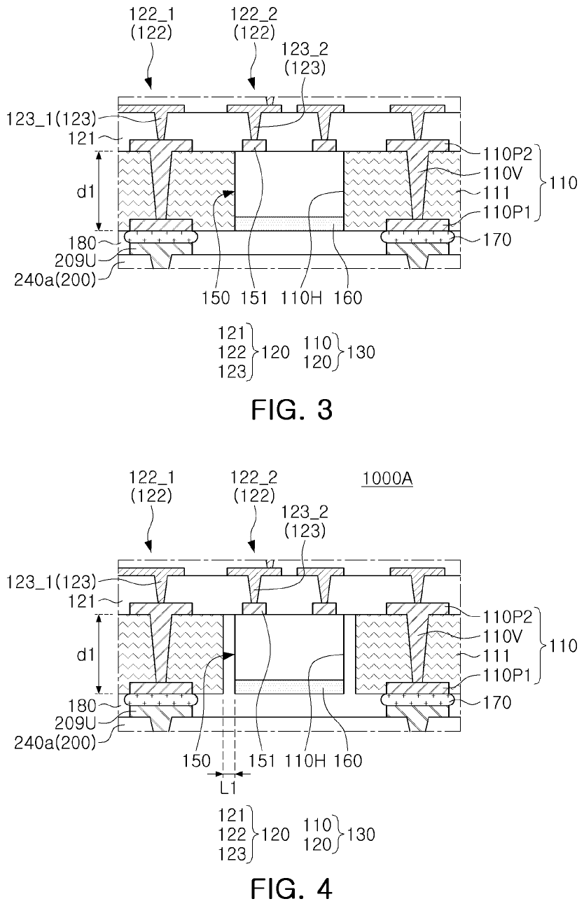

FIG. 3 is a partially enlarged view of a semiconductor package according to some example implementations. FIG. 3 is a partially enlarged view illustrating region ‘A’ of FIG. 2A.

Referring to FIGS. 1, 2A, 2B and 3, a semiconductor package 1000 may include a lower structure LS, an upper structure US, an underfill layer 180 between the lower and upper structures LS and US, and an external connection terminal 300 disposed at a lower portion of the lower structure LS.

The lower structure LS may include a core substrate 201 having a conductive via 203, interconnection structures 201a and 201b on the core substrate 201, a plurality of first to fourth build-up layers 210, 220, 230 and 240, and a plurality of passivation layers 250. The lower structure LS may be referred to as a core structure 200 (hereinafter, ‘core structure 200’).

The core substrate 201 may be disposed in the center of the core structure 200. The core substrate 201 may include an organic insulating substrate such as a glass epoxy substrate, a polyimide substrate, a bismaleimide triazine substrate, or the like, but the present disclosure is not limited thereto.

The conductive via 203 may be formed by extending through the core substrate 201. The conductive via 203 may include a conductive material such as copper and a copper alloy. In some implementations, the conductive via 203 may further include a barrier layer surrounding the conductive material. The conductive via 203 may provide an electrical connection path from one side of the core substrate 201 to the other side opposite to the one side.

The interconnection structures 201a and 201b may include an upper interconnection structure 201a on an upper surface of the core substrate 201 and a lower interconnection structure 201b on a lower surface of the core substrate 201. At least portions of the upper and lower interconnection structures 201a and 201b may extend by extending through the core substrate 201 and may surround the conductive via 203. Each of the upper and lower interconnection structures 201a and 201b may include, for example, at least one of aluminum (Al), gold (Au), cobalt (Co), copper (Cu), nickel (Ni), lead (Pb), tantalum (Ta), tellurium (Te), titanium (Ti), or tungsten (W).

The plurality of first build-up layers 210 may include a first upper build-up layer 210a built-up on an upper surface of the core substrate 201 and a first lower build-up layer 210b built-up on a lower surface of the core substrate 201. The first upper build-up layer 210a may cover the upper interconnection structure 201a, and the first lower build-up layer 210b may cover the lower interconnection structure 201b.

The plurality of second build-up layers 220 may include a second upper build-up layer 220a built-up on an upper surface of the first upper build-up layer 210a and a second lower build-up layer 220b built-up on a lower surface of the first lower build-up layer 210b.

The plurality of third build-up layers 230 may include a third upper build-up layer 230a built-up on an upper surface of the second upper build-up layer 220a and a third lower build-up layer 230b built-up on a lower surface of the second lower build-up layer 220b.

A plurality of fourth build-up layers 240 may include a fourth upper build-up layer 240a built-up on an upper surface of the third upper build-up layer 230a and a fourth lower build-up layer 240b built-up on a lower surface of the third lower build-up layer 230b. The number of build-up layers of the core structure 200 may not be limited to those illustrated. The core structure 200 may further include, for example, separate additional build-up layers.

Each of the first to fourth upper build-up layers 210a, 220a, 230a and 240a and the first to fourth lower build-up layers 210b, 220b, 230b and 240b may include an interlayer insulating layer 205, an interconnection via 207 and an interconnection pattern 209.

The interlayer insulating layer 205 may include Flowable Oxide (FOX), Tonen SilaZen (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. The interlayer insulating layer may be formed using a chemical vapor deposition (CVD) process, a flowable-CVD process, or a spin coating process.

The interconnection pattern 209 may be formed on the interlayer insulating layer 205. The interconnection pattern 209 may include interconnection patterns 209U and 209L disposed on an outermost side based on the core substrate 201. The interconnection pattern 209U may refer to, for example, an interconnection pattern of an uppermost layer formed on an upper surface of the fourth upper build-up layer 240a, and the interconnection pattern 209L may refer to, for example, an interconnection pattern of a lowermost layer formed on a lower surface of the fourth lower build-up layer 240b. In some implementations, the interconnection pattern 209U of the uppermost layer may be referred to as a front pad, and the interconnection pattern 209L of the lowermost layer may be referred to as a rear pad.

The interconnection via 207 may electrically connect the interconnection pattern 209 and an interconnection pattern disposed at a lower portion of the interlayer insulation layer 205 by extending through the interlayer insulation layer 205. The interconnection via 207 and the interconnection pattern 209 may include a conductive material. The interconnection vias 207 and the interconnection patterns 209 may include, for example, at least one of aluminum (Al), gold (Au), cobalt (Co), copper (Cu), nickel (Ni), lead (Pb), tantalum (Ta), tellurium (Te), titanium (Ti), or tungsten (W).

The plurality of passivation layers 250 may include an upper passivation layer 250a on the fourth upper build-up layer 240a and a lower passivation layer 250b on the fourth lower build-up layer 240b. The upper passivation layer 250a may have an opening exposing at least a portion of the interconnection pattern 209U of the uppermost layer. The lower passivation layer 250b may have a plurality of open portions exposing the interconnection pattern 209L of the lowermost layer. The plurality of passivation layers 250 may include a photosensitive insulating material, for example, a photosensitive insulating resin, but the present disclosure is not limited thereto.

The upper structure US may include an interposer substrate 130, at least one semiconductor chip 141 or 142, an underfill resin 145, a passive device 150, and a connection bump 170. The interposer substrate 130 may include a rigid structure 110 and a redistribution substrate 120, and the at least one semiconductor chip 141 or 142 may include at least one first semiconductor chip 141 and a second semiconductor chip 142. The upper structure US may be referred to as a unit semiconductor package 100 (or ‘unit package structure’).

The redistribution substrate 120 may have a first surface S1 and a second surface S2, opposite to the first surface S1, and may include at least one first insulating layer 121, at least one redistribution pattern 122 disposed on the first insulating layer 121, and at least one redistribution via 123 extending through the first insulating layer 121 and electrically connected to the redistribution pattern 122.

The first insulating layer 121 may include an insulating resin. The insulating resin may include a thermosetting resin such as an epoxy resin or a thermoplastic resin such as a polyimide. The first insulating layer 121 may include a photosensitive resin such as a Photoimageable Dielectric (PID) resin. In this case, the first insulating layer 121 may be formed to be thinner, and a fine redistribution pattern 122 and a redistribution via 123 may be formed.

The redistribution pattern 122 may include first to third redistribution patterns 122_1, 122_2 and 122_3. The first redistribution pattern 122_1 may electrically connect the first semiconductor chip 141 and an upper pad 110P2 of the rigid structure 110. The second redistribution pattern 122_2 may electrically connect the first semiconductor chip 141 and the connection terminal 151 of the passive device 150. The third redistribution pattern 122_3 may electrically connect the first semiconductor chip 141 and the second semiconductor chip 142.

The redistribution pattern 122 may include a metallic material including, for example, copper (Cu), aluminum (Al), silver (Ag), tin (Sn), gold (Au), nickel (Ni), lead (Pb), titanium (Ti), or alloys thereof.

The redistribution via 123 may include a first redistribution via 123_1 electrically connected to the first redistribution pattern 122_1, a second redistribution via 123_2 electrically connected to the second redistribution pattern 122_2, and a third redistribution via 123_3 electrically connected to the third redistribution pattern 122_3. The redistribution via 123 may include a metallic material including, for example, copper (Cu), aluminum (Al), silver (Ag), tin (Sn), gold (Au), nickel (Ni), lead (Pb), titanium (Ti), or alloys thereof. The redistribution via 123 may have a filled via shape in which the metallic material is filled in a via hole or a conformal via shape in which the metallic material is formed along an inner wall of the via hole.

The rigid structure 110 may be disposed on the second surface S2 of the redistribution substrate 120. The rigid structure 110 may include a second insulating layer 111, a lower pad 110P1 disposed at a lower portion of the second insulating layer 111, an upper pad 110P2 disposed on an upper portion of the second insulating layer 111, and a through-via 110V extending through the second insulating layer 111 and electrically connecting the lower and upper pads 110P1 and 110P2.

The second insulating layer 111 may include an insulating material different from the first insulating layer 121. The rigidity of the insulating material of the second insulating layer 111 may be greater than the rigidity of the insulating material of the first insulating layer 121. The second insulating layer 111 may include, for example, a resin in which an inorganic filler and/or glass fiber (Glass Fiber, Glass Cloth or Glass Fabric) are impregnated in each of a thermosetting resin such as an epoxy resin or a thermoplastic resin such as a polyimide. The second insulating layer 111 may include an insulating film formed of an organic material, for example, an Ajinomoto Build-up Film (ABF). The second insulating layer 111 may further include, for example, a prepreg, FR-4, or Bismaleimide Triazine (BT). The second insulating layer 111 may have a first thickness d1 in a vertical direction. The first thickness d1 may be about 150 μm or less. In some implementations, the first thickness d1 may have, for example, a range of about 50 μm or more and about 150 μm or less. In some implementations, the first thickness d1 may have a range of, for example, about 60 μm or more and about 150 μm or less. In some implementations, the first thickness d1 may have a range of, for example, about 60 μm or more and about 100 μm or less.

The upper pad 110P2 may be electrically connected to the redistribution pattern 122 through the redistribution via 123. The upper pad 110P2 may be electrically connected to the first redistribution pattern 122_1 through, for example, the first redistribution via 123_1. The upper pad 110P2 may be disposed in the first insulating layer 121 of the redistribution substrate 120. The lower and upper pads (110P1 and 110P2) may include a metallic material including, for example, copper (Cu), aluminum (Al), silver (Ag), tin (Sn), gold (Au), nickel (Ni), lead (Pb), titanium (Ti), or alloys thereof.

The through-via 110V may have a tapered shape. A horizontal width of the through-via 110V may decrease as the through-via 110V moves away from a lower surface of the upper pad 110P2 and approaches an upper surface of the lower pad 110P1. The through-via 110V may include a metallic material including, for example, copper (Cu), aluminum (Al), silver (Ag), tin (Sn), gold (Au), nickel (Ni), lead (Pb), titanium (Ti), or alloys thereof. A maximum diameter of the through-via 110V in a horizontal direction may be about 80 μm or less. In some implementations, a maximum diameter of the through-via 110Vin the horizontal direction may be in a range of about 30 μm or more and about 80 μm or less. In some implementations, the maximum diameter of the through-via 110V in the horizontal direction may be in a range of about 40 μm or more and about 60 μm or less.

The rigid structure 110 may further include a through-hole 110H. The through-hole 110H may be formed by extending through the rigid structure 110.

The passive device 150 may be disposed in the through-hole 110H of the rigid structure 110, and may be electrically connected to the first semiconductor chip 121 through the redistribution pattern 122 and the redistribution via 123. The passive device 150 may be electrically connected to the first semiconductor chip 141 through, for example, the second redistribution pattern 122_2 and the second redistribution via 123_2.

The passive device 150 may have an active surface and a connection terminal 151 disposed on the active surface. The passive device 150 may be mounted on the second surface S2 of the redistribution substrate 120 in a flip-chip manner. The active surface of the passive device 150 may be in contact with at least a portion of the second surface S2 of the redistribution substrate 120, and the connection terminal 151 may be disposed in the first insulating layer 121 of the redistribution substrate 120 and may be in direct contact with the second redistribution via 123_2. An upper surface of the connection terminal 151 may be on substantially the same plane as that of an upper surface of the upper pad 110P2 of the rigid structure 110. The connection terminal 151 may include a metallic material including, for example, copper (Cu), aluminum (Al), silver (Ag), tin (Sn), gold (Au), nickel (Ni), lead (Pb), titanium (Ti), or alloys thereof.

The passive device 150 may be disposed in parallel with the through-via 110V.

The passive device 150 may include, for example, a capacitor, an inductor, and beads. The passive device 150 may improve Signal Integrity (SI) and/or Power Integrity (PI) characteristics of the semiconductor package.

The present disclosure may shorten an electrical connection path between the passive device 150 and the first semiconductor chip 141 by providing a rigid structure 110 having a through-hole 110H, and disposing the passive device 150 in the through-hole H. Accordingly, the Signal Integrity (SI) and/or Power Integrity (PI) characteristics may be further improved.

An adhesive layer 160 disposed at a lower portion of the passive device 150 may be further included in the through-hole 110H of the rigid structure 110. The adhesive layer 160 may be disposed on the inactive surface opposite to the active surface of the passive device 150. A lower surface of the adhesive layer 160 may be on substantially the same plane as that of a lower surface of the lower pad 110P1 of the rigid structure 110 or a lower surface of the second insulating layer 111. The adhesive layer 160 may be a Non Conductive Film (NCF), but is not limited thereto, and may include, for example, any type of polymer film capable of undergoing a thermocompression process.

A connection bump 170 disposed at a lower portion of the rigid structure 110 may be included. The connection bump 170 may be disposed between the upper and lower structures US and LS, and may electrically connect the lower pad 110P1 of the rigid structure 110 and the interconnection pattern 209U of the core structure 200. A thickness of the connection bump 170 in a vertical direction may be substantially the same as or smaller than a thickness of the lower pad 110P1 of the rigid structure 110 in the vertical direction. The connection bump 170 may include, for example, tin (Sn), indium (In), bismuth (Bi), antimony (Sb), copper (Cu), silver (Ag), zinc (Zn), lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn and Sn—Bi—Zn.

A semiconductor chip 140 may be disposed on the first surface S1 of the redistribution substrate 120 and may be electrically connected to the redistribution pattern 122 through the redistribution via 123. The semiconductor chip 140 may include at least one first and second semiconductor chip 141 or 142. For example, at least one first semiconductor chip 141 may be electrically connected to the first redistribution pattern 122_1 through the first redistribution via 123_1. The second semiconductor chip 142 may be electrically connected to the second redistribution pattern 122_2 through the second redistribution via 123_2. The first and second semiconductor chips 141 and 142 may be electrically connected to each other through the third redistribution via 123_3 and the third redistribution pattern 122_3. The semiconductor chips 141 and 142 may be a logic chip or a memory chip. The logic chip may include, for example, a central processing unit (CPU), a graphics processing unit (GPU), a field programmable gate array (FPGA), a digital signal processor (DSP), a cryptographic processor, a microprocessor, a microcontroller, an analog-to-digital converter, and an application-specific integrated circuit (ASIC). The memory chip may include, for example, a volatile memory device such as a dynamic RAM (DRAM) and a static RAM (SRAM) or a nonvolatile memory device such as a phase change RAM (PRAM), a magnetic RAM (MRAM), a resistive RAM (RRAM) and a flash memory, or a high-performance memory device such as a high bandwidth memory (HBM) and a hybrid memory cubic (HMC). At least one first semiconductor chip 141 may include the memory chip, and the second semiconductor chip 142 may include the logic chip.

In one example, the first and second semiconductor chips 141 and 142 may be mounted on the redistribution substrate 120 in a flip-chip bonding manner. For example, the first and second semiconductor chips 141 and 142 may be disposed so that the active surface on which a connection pad is disposed faces the first surface S1 and may be connected to the redistribution via 123 through a bump structure 135. The bump structure 135 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn and Sn—Bi—Zn. The connection pad may include, for example, a metallic material such as aluminum (Al).

An underfill resin 145 filling lower portions of the first and second semiconductor chips 141 and 142 may be formed on the first surface S1 of the redistribution substrate 120. For example, the underfill resin 145 may fill a space between the first surface S1 and the first and second semiconductor chips 141 and 142, and may be formed to surround the bump structures 135. The underfill resin 145 may include a polymer material such as an epoxy resin.

The underfill layer 180 may be formed between the lower and upper structures LS and US. The underfill layer 180 may fill an opening of the upper passivation layer 250a, and may cover an interconnection pattern 209U of an uppermost layer and the connection bump 170. The underfill layer 180 may fix the unit semiconductor package 100 onto the core structure 200, between the unit semiconductor package 100 and the core structure 200. The underfill layer 180 may include a polymer material such as an epoxy resin.

The external connection terminal 300 may be disposed at the lower portion of the lower structure LS. The external connection terminal 300 may be disposed at a lower portion of the interconnection pattern 209L of a lowermost layer exposed by the plurality of open portions of the lower passivation layer 250b. The external connection terminal 300 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn and Sn—Bi—Zn.

FIG. 4 is a partially enlarged view of a semiconductor package according to some example implementations.

Referring to FIG. 4, a semiconductor package 1000A may be the same as or similar to that described with reference to FIGS. 1 to 3, except that a sidewall of the through-hole 110H of the rigid structure 110 is spaced apart from a sidewall of the passive device 150.

A maximum width of the through-hole 110H of the rigid structure 110 in the horizontal direction may be greater than a width of the passive device 150 in the horizontal direction. Accordingly, the sidewall of the passive device 150 may be spaced apart from the sidewall of the through-hole 110H of the rigid structure 110 by a first distance L1.

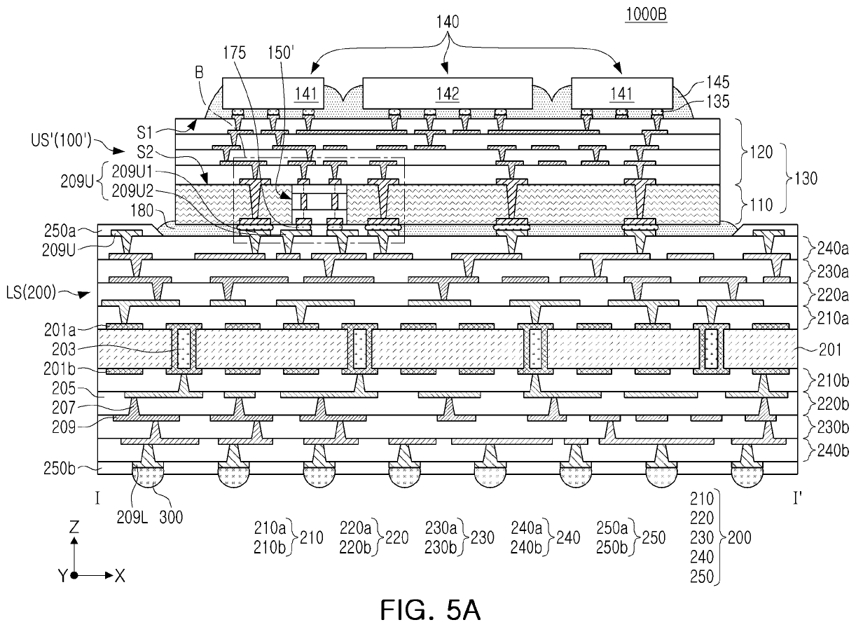

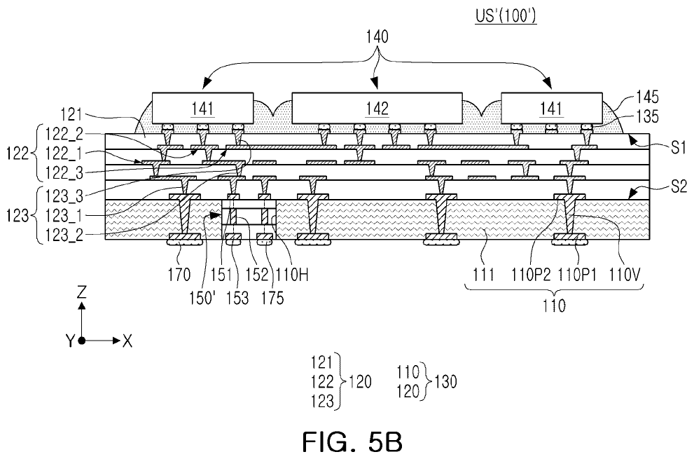

FIG. 5A is a cross-sectional view of a semiconductor package taken along line I-I′ of FIG. 1.

FIG. 5B is a partially enlarged view of a semiconductor package according to some example implementations. FIG. 5B is a partially enlarged view illustrating an upper structure US′ of FIG. 5A.

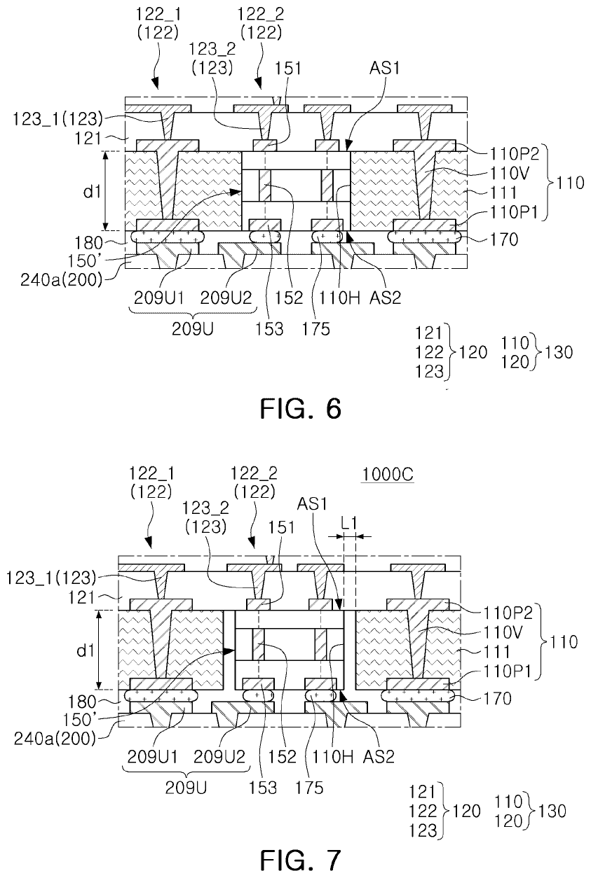

FIG. 6 is a partially enlarged view of a semiconductor package according to some example implementations. FIG. 6 is a partially enlarged view illustrating region ‘B’ of FIG. 5A.

Referring to FIGS. 5A, 5B and 6, a semiconductor package 1000B may be the same as or similar to that described with reference to FIGS. 1 to 4, except that a passive device 150′ further includes a through-electrode 152.

Referring to FIG. 6, a passive device 150′ may include a first connection terminal 151 on a first active surface AS1 and a second connection terminal 153 on a second active surface AS2, opposite to the first active surface AS1, and the through-electrode 152 electrically connecting the first and second connection terminals 151 and 153. The first and second connection terminals 151 and 153 may include a metallic material, for example, copper (Cu), aluminum (Al), silver (Ag), tin (Sn), gold (Au), nickel (Ni), lead (Pb), titanium (Ti), or alloys thereof. In some implementations, the first connection terminal 151 may be referred to as a connection terminal, and the second connection terminal 153 may be referred to as an opposite connection terminal.

A lower surface of the second connection terminal 153 may be on substantially the same plane as that of the second active surface AS2. The lower surface of the second connection terminal 153 may be on substantially the same plane as that of a lower surface of the lower pad 110P1. The second active surface AS2 may be on substantially the same plane as that of the lower surface of the second insulating layer 111.

A region in which the through-electrode 152 is disposed may be a semiconductor substrate including a semiconductor element such as silicon (Si) or germanium (Ge), or including a compound semiconductor such as silicon carbide (SiC), gallium arsenide (GaAs), indium arsenide (InAs) or indium phosphide (InP). The region in which the through-electrode 152 is disposed may be a portion of a silicon wafer used in the manufacture of a semiconductor element.

In each of a region between the first connection terminal 151 and the through-electrode 152 and a region between the second connection terminal 153 and the through-electrode 152, at least one interconnection layer may be formed.

The interconnection pattern 209U of an uppermost layer of the core structure 200 may be defined as having a first interconnection pattern 209U1 and a second interconnection pattern 209U2. In some implementations, the first interconnection pattern 209U1 of an uppermost layer may be referred to as a first front pad, the second interconnection pattern 209U2 of an uppermost layer may be referred to as a second front pad, and the interconnection pattern 209L of a lowermost layer may be referred to as a rear pad. The first interconnection pattern 209U1 may have substantially the same characteristics as the interconnection pattern 209U described with reference to FIGS. 1 to 4, and detailed descriptions thereof may be omitted.

The second interconnection pattern 209U2 may be formed to overlap at least a portion of the second connection terminal 153 in the vertical direction. The second interconnection pattern 209U2 may be formed on substantially the same level as the first interconnection pattern 209U1. The second interconnection pattern 209U2 may include, for example, at least one of aluminum (Al), gold (Au), cobalt (Co), copper (Cu), nickel (Ni), lead (Pb), tantalum (Ta), tellurium (Te), titanium (Ti) or tungsten (W).

The upper structure US may further include a connection structure 175 disposed between the second connection terminal 153 and the second interconnection pattern 209U2 and electrically connecting the second connection terminal 153 and the second interconnection pattern 209U2. The connection structure 175 may be formed on substantially the same level as the connection bump 170. A thickness of the connection structure 175 in the vertical direction may be substantially the same as or smaller than a thickness of the second connection terminal 153 in the vertical direction. The connection structure 175 may have substantially the same characteristics as the connection bump 170. The connection structure 175 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn and Sn—Bi—Zn. In some implementations, the connection structure 175 may be narrower in the horizontal direction than the connection bump 170. For example, a largest width of the connection bump 170 in the horizontal direction may be greater than a largest width of the connection structure 175 in the horizontal direction.

FIG. 7 is a partially enlarged view of a semiconductor package according to some example implementations.

Referring to FIG. 7, a semiconductor package 1000C may be the same as or similar to that described with reference to FIGS. 1 to 6, except that the sidewall of the through-hole 110H of the rigid structure 110 is spaced apart from a sidewall of the passive device 150′.

A maximum width of the through-hole 110H of the rigid structure 110 in the horizontal direction may be greater than the width of the passive device 150′ in the horizontal direction. Accordingly, the sidewall of the passive device 150′ may be spaced apart from the sidewall of the through-hole 110H of the rigid structure 110 by the first distance L1.

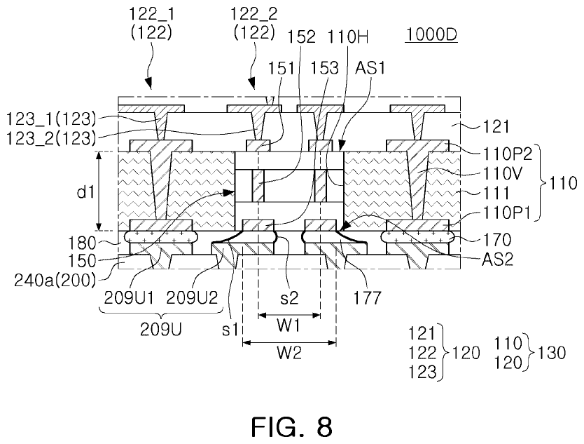

FIG. 8 is a partially enlarged view of a semiconductor package according to some example implementations.

Referring to FIG. 8, a semiconductor package 1000D may be the same as or similar to that described with reference to FIGS. 1 to 7, except that the semiconductor package 1000D includes a connection structure 177 between the second connection terminal 153 and the second interconnection pattern 209U2.

The connection structure 177 may have different properties from the connection bump 170, unlike the connection structure 175 described with reference to FIGS. 5A to 7. The connection structure 177 may include, for example, a conductive paste. The connection structure 177 may include, for example, a polymer binder and fine metal particles dispersed in the polymer binder. The metal particles may include at least one of silver (Ag), copper (Cu), or gold (Au).

The connection structure 177 may have a first surface S1 facing the closest connection bump 170 and a second surface S2 opposite to the first surface S1. A surface inclination of the first surface S1 may gradually become gentler as the first surface S1 approaches the second interconnection pattern 209U2 based on an upper surface of the second interconnection pattern 209U2. This may be interpreted as being because a distance W1 between centers of the second connection terminals 153 adjacent to each other is less than a distance W2 between centers of the second interconnection patterns 209U2 adjacent to each other.

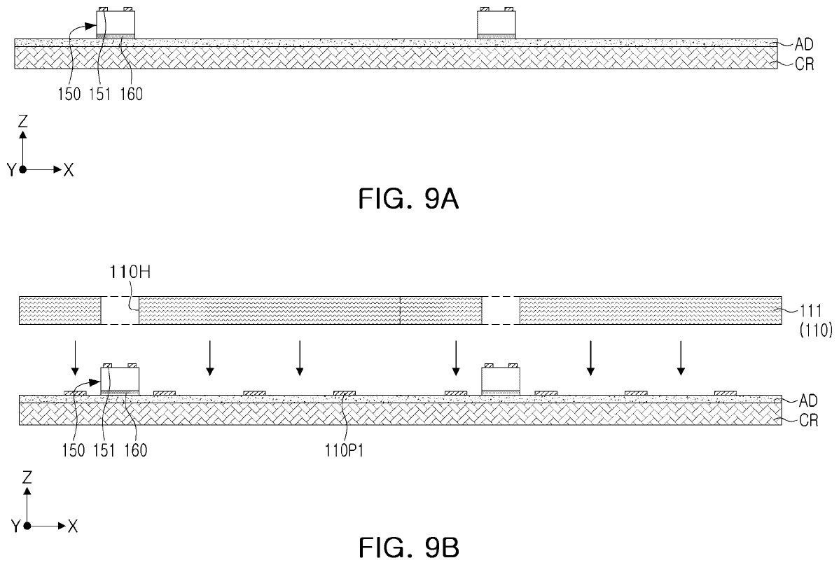

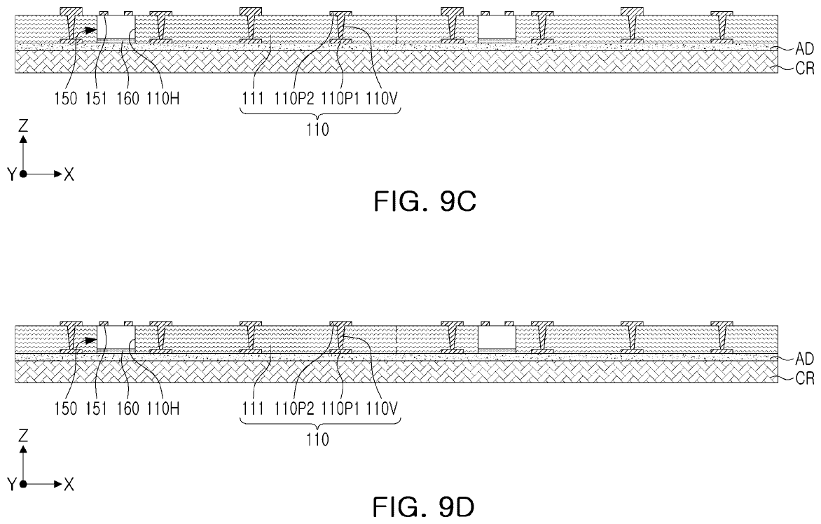

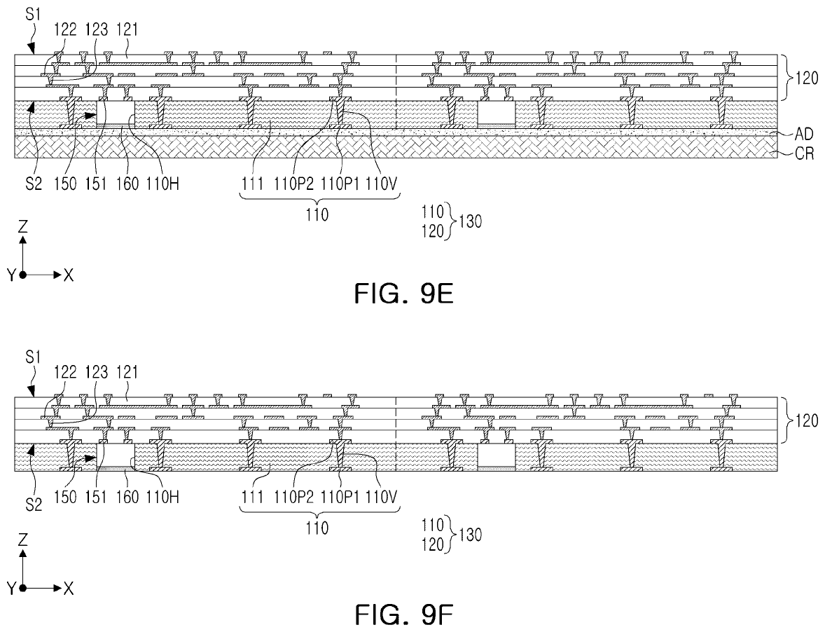

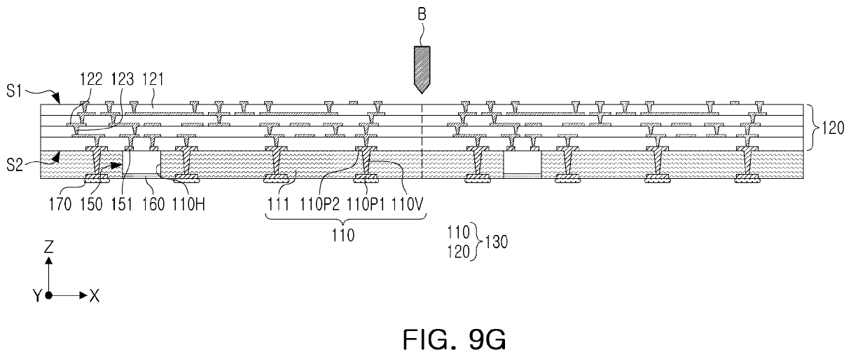

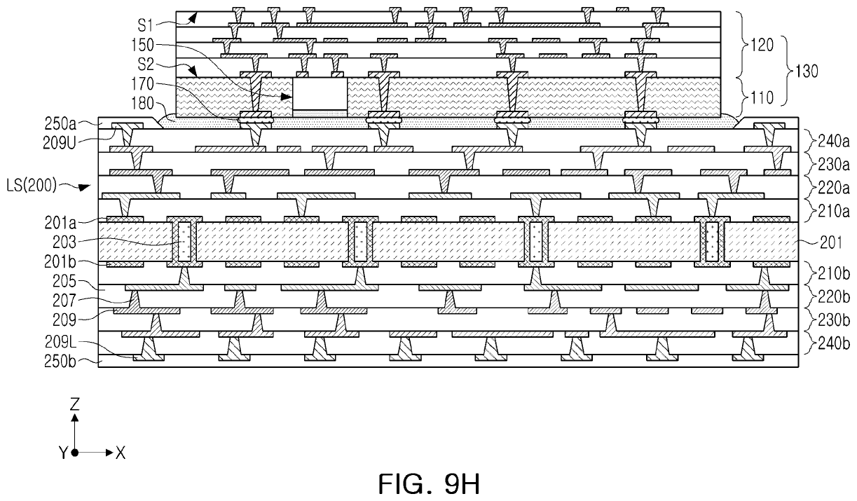

FIGS. 9A to 9H are cross-sectional views illustrating a process order for describing a method of manufacturing a semiconductor package according to some example implementations. FIGS. 9A to 9H may be process diagrams illustrating a method of manufacturing a semiconductor package 1000 illustrated in FIGS. 2A, 2B, and 3.

Referring to FIG. 9A, a plurality of passive devices 150 may be formed on a carrier substrate CR.

The carrier substrate CR may be a temporary support in the form of a wafer or panel. A bonding material layer AD including a curable resin layer may be disposed on the carrier substrate CR. Each of the plurality of passive devices 150 may have an active surface, an inactive surface opposite to the active surface, and a connection terminal 151 formed on the active surface. Each of the plurality of passive devices 150 may be fixed onto the carrier substrate CR by an adhesive layer 160 formed on the inactive surface.

Referring to FIG. 9B, an insulating layer 111 (or a rigid structure 110) having a through-hole 110H may be formed on the carrier substrate CR.

A conductive material may be deposited and patterned on the bonding material layer AD to form a lower pad 110P1. Then, an insulating layer 111 having the through-hole 110H may be formed on the bonding material layer AD so that the passive device 150 is disposed in the through-hole 110H. The insulating layer 111 may include an insulating film formed of an organic material, for example, Ajinomoto Build-up Film (ABF). A width of a sidewall of the through-hole 110H in the horizontal direction may be substantially the same as the width of the passive device 150 in the horizontal direction, but the present disclosure is not limited thereto. For example, a width of the sidewall of the through-hole 110H in the horizontal direction may be greater than the width of the passive device 150 in the horizontal direction, and in this case, the sidewall of the through-hole 110H may be spaced apart from the passive device 150 (see FIG. 4).

Referring to FIG. 9C, a rigid structure 110 may be formed by forming a through-via 110V and an upper pad 110P2.

A through-hole extending through the insulating layer 111 and exposing at least a portion of an upper surface of the lower pad 110P1 may be formed. A conductive material may be filled in the through-hole to form the through-via 110V. Then, a conductive material layer on the insulating layer 111 may be patterned to form upper pads 110P2. The upper surface of the connection terminal 151 of the passive device 150 and upper surfaces of the upper pads 110P2 may be on different planes.

Referring to FIG. 9D, a connection terminal 151 of the passive device 150 and the upper pads 110P2 may be made to be on substantially the same plane.

The connection terminal 151 of the passive device 150 and the upper pads 110P2 may be ground so that the upper surface of the connection terminal 151 of the passive device 150 and the upper surfaces of the upper pads 110P2 may be on substantially the same plane.

Referring to FIG. 9E, a redistribution substrate 120 may be formed on the rigid structure 110.

An insulating layer 121 covering the upper pad 110P2 on the rigid structure 110 and the connection terminal 151 of the passive device 150, a redistribution via 123 extending through the insulating layer 121 and contacting the upper pad 110P2 and the connection terminal 151, and a redistribution pattern 122 connected to the redistribution via 123 may be formed. Then, at least one layer of the insulating layer 121 covering the redistribution pattern 122, at least one layer of the redistribution via 123 extending through the insulating layer 121 and at least one layer of the redistribution pattern 122 connected to the redistribution via 123 may be sequentially formed, thereby forming a redistribution substrate 120. The redistribution substrate 120 may be defined to have a first surface S1 and a second surface S2, opposite to the first surface S1.

The redistribution substrate 120 may be formed on the rigid structure 110 so that an active surface of the passive device 150 is mounted on the second surface S2 of the redistribution substrate 120 in a flip chip manner. Accordingly, a single interposer substrate 130 in which a plurality of components extend in a horizontal direction (e.g., X-direction) may be formed.

Referring to FIG. 9F, the carrier substrate CR and the bonding material layer AD may be removed.

The carrier substrate CR and the bonding material layer AD may be removed, so that a lower surface of the first insulating layer 111, the lower surface of the lower pad 110P1 and the lower surface of the adhesive layer 160 may be exposed.

Referring to FIG. 9G, a connection bump 170 may be formed on the lower surface of the lower pad 110P1, and a single interposer substrate 130 may be formed using a blade B.

A lower surface of the rigid structure 110 may be made to face up, so that the connection bump 170 may be formed on the lower surface of the lower pad 110P1. Then, the first surface S1 of the redistribution substrate 120 may be made to face up, and a single interposer substrate 130 may be cut in a vertical direction (e.g., Z-direction) using the blade B, thereby forming a plurality of interposer substrates 130.

Referring to FIG. 9H, the interposer substrate 130 may be mounted on the core structure 200, and the interposer substrate 130 may be fixed onto the core structure 200 using the underfill layer 180.

The core structure 200 including a core substrate 201 having a conductive via 203, interconnection structures 201a and 201b on the core substrate 201, a plurality of first to fourth build-up layers 210, 220, 230 and 240, and a plurality of passivation layers 250 may be provided. Specifically, the core structure 200 having an upper passivation layer 250a having an opening formed therein exposing at least a portion of the interconnection pattern 209U of the uppermost layer may be provided.

The interposer substrate 130 may be mounted on the core structure 200 so that the connection bump 170 may come into contact with the interconnection pattern 209U of the uppermost layer exposed by the opening. Then, the underfill layer 180 filling the opening and surrounding the connection bump 170 may be formed, thereby fixing the interposer substrate 130 onto the core structure 200.

Then, a semiconductor chip 140 including at least one first semiconductor chip 141 and at least one second semiconductor chip 142 may be formed on the first surface S1 of the redistribution substrate 120. The at least one first semiconductor chip 141 and the at least one second semiconductor chip 142 may be fixed onto the first surface S1 of the redistribution substrate 120 by the underfill resin 145. Referring to FIG. 2B together, the at least one first semiconductor chip 141 and the upper pad 110P2 of the rigid structure 110 may be electrically connected by the first redistribution pattern 122_1, and the at least one first semiconductor chip 141 and the passive device 150 may be electrically connected by the second redistribution pattern 122_2, and the at least one first semiconductor chip 141 and the at least one second semiconductor chip 142 may be electrically connected by the third redistribution pattern 122_3.

Next, a plurality of open portions extending through the lower passivation layer 250b and exposing at least a portion of the interconnection pattern 209L of the lowermost layer may be formed. Then, an external connection terminal 300 may be formed on the interconnection pattern 209L of the lowermost layer exposed by the plurality of open portions, thereby forming a semiconductor package 1000.

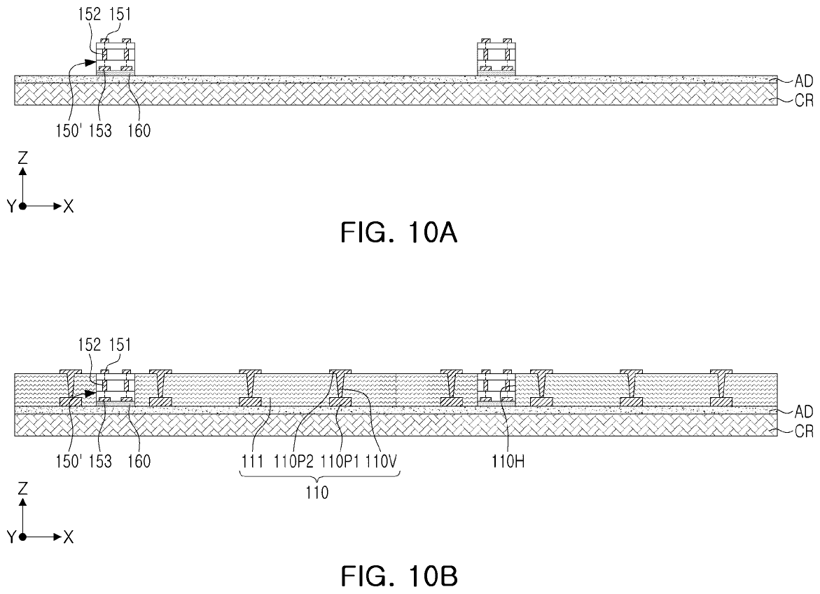

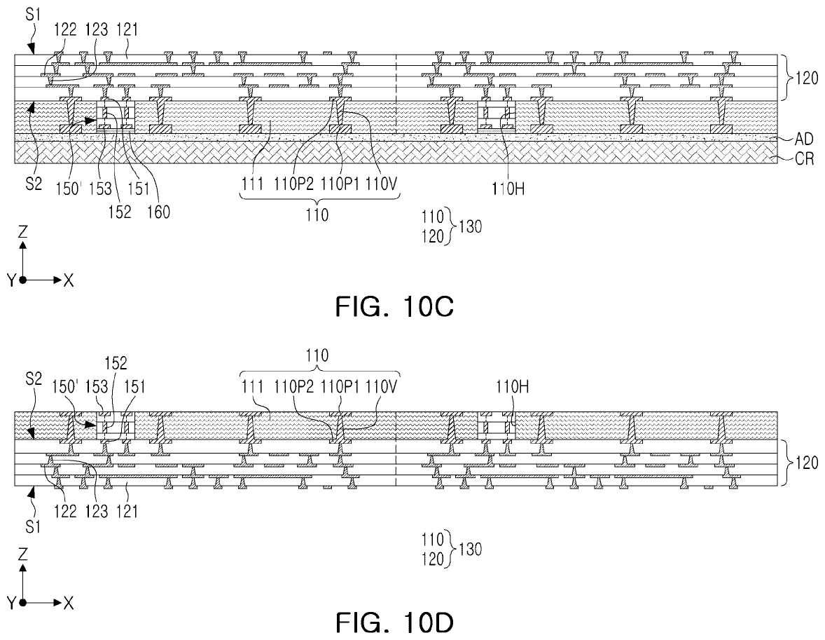

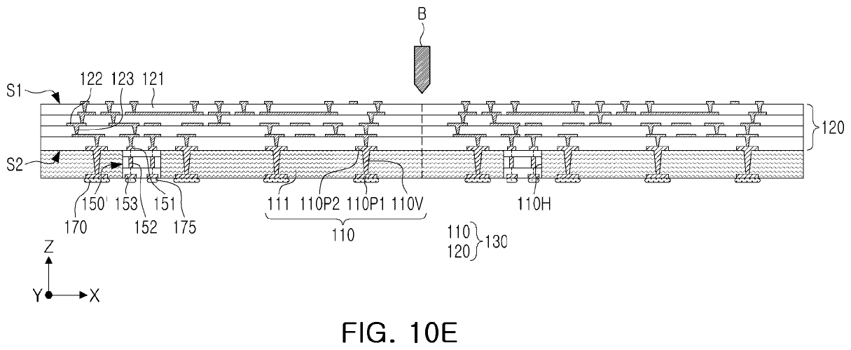

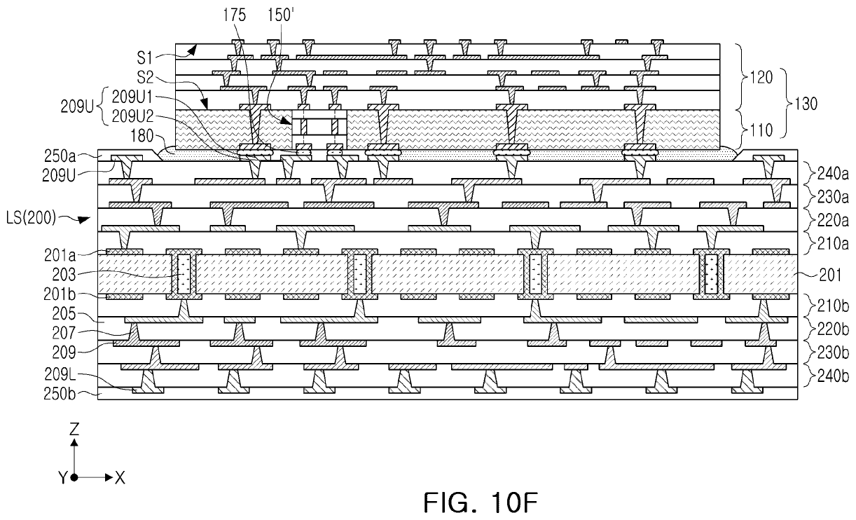

FIGS. 10A to 10F are cross-sectional views illustrating a method of manufacturing a semiconductor package according to some example implementations according to the process order. FIGS. 10A to 10F may be process diagrams illustrating a method of manufacturing the semiconductor package 1000B illustrated in FIGS. 5A, 5B and 6.

Referring to FIG. 10A, a plurality of passive devices 150′ may be formed on a carrier substrate CR.

The carrier substrate CR may be a temporary support in the form of a wafer or panel. A bonding material layer AD including a curable resin layer may be disposed on the carrier substrate CR.

Each of the plurality of passive devices 150′ may have a first active surface AS1 (see FIG. 6), a second active surface AS2 (see FIG. 6) opposite to the first active surface, first connection terminals 151 formed on the first active surface, second connection terminals 153 formed on the second active surface, and a through-electrode 152 electrically connecting the first and second connection terminals 151 and 153.

Each of the plurality of passive devices 150′ may be fixed onto the carrier substrate CR by an adhesive layer 160 formed on the second active surface.

Referring to FIG. 10B, a rigid structure 110 having a through-hole 110H may be formed on the carrier substrate CR.

A conductive material may be deposited and patterned on a bonding material layer AD to form a lower pad 110P1. Then, an insulating layer 111 having a through-hole 110H may be formed on the bonding material layer AD so that a passive device 150′ is positioned in the through-hole 110H. The insulating layer 111 may include an insulating film formed of an organic material, for example, Ajinomoto Build-up Film (ABF). The width of the sidewall of the through-hole 110H in the horizontal direction may be substantially the same as a width of the passive device 150′ in the horizontal direction, but the present disclosure is not limited thereto. For example, the width of the sidewall of the through-hole 110H in the horizontal direction may be greater than the width of the passive device 150′ in the horizontal direction, and in this case, the sidewall of the through-hole 110H may be spaced apart from the passive device 150′ (see FIG. 7).

Then, a through-hole extending through the insulating layer 111 and exposing at least a portion of an upper surface of the lower pad 110P1 may be formed. A conductive material may be filled in the through-hole to form the through-via 110V. Then, the conductive material on the insulating layer 111 may be patterned to form upper pads 110P2. An upper surface of the first connection terminal 151 of the passive device 150 and upper surfaces of the upper pads 110P2 may be on different planes.

Then, the first connection terminal 151 of the passive component 150′ and the upper pads 110P2 may be ground so that an upper surface of the first connection terminal 151 of the passive component 150′ and an upper surface of the upper pads 110P2 may be on substantially the same plane.

Referring to FIG. 10C, a redistribution substrate 120 may be formed on the rigid structure 110.

An insulating layer 121 covering the upper pad 110P2 on the rigid structure 110 and the first connection terminal 151 of the passive component 150′, a redistribution via 123 extending through the insulating layer 121 and contacting the upper pad 110P2 and the connection terminal 151, and a redistribution pattern 122 connected to the redistribution via 123 may be formed. Then, at least one layer of the insulating layer 121 covering the redistribution pattern 122, at least one layer of the redistribution via 123 extending through the insulating layer 121, and at least one layer of the redistribution pattern 122 connected to the redistribution via 123 may be sequentially formed, thereby forming the redistribution substrate 120. The redistribution substrate 120 may be defined to have a first surface S1 and a second surface S2 opposite to the first surface S1.

The redistribution substrate 120 may be formed on the rigid structure 110 so that the first active surface (‘AS1’ of FIG. 6) of the passive device 150′ may be mounted on the second surface S2 of the redistribution substrate 120 in a flip chip manner. Accordingly, a single interposer substrate 130 in which a plurality of components extends in the horizontal direction (e.g., the X-direction) may be formed.

Referring to FIG. 10D, a lower surface of the rigid structure 110 may be provided to face up, and the adhesive layer 160 (see FIG. 10C) may be removed.

The carrier substrate CR and the bonding material layer AD may be removed, and the lower surface of the rigid structure 110 may be provided to face up. Then, the adhesive layer 160 (see FIG. 10C) may be removed so as to expose the second active surface AS2 (see FIG. 6) or a second connection terminal 152 of the passive device 150′. Accordingly, at least portions of the insulating layer 111 and the lower pad 110P1 of the rigid structure 110 may be removed.

Referring to FIG. 10E, a connection bump 170 may be formed on the lower surface of the lower pad 110P1, a connection structure 175 may be formed on the lower surface of the second connection terminal 153 of the passive component 150′, and a single interposer substrate 130 may be formed using the blade B.

The connection bump 170 may be formed on the lower surface of the lower pad 110P1, and the connection structure 175 may be formed on the lower surface of the second connection terminal 153. The connection structure 175 may have substantially the same properties as the connection bump 170. Then, the first surface S1 of the redistribution substrate 120 may be made to face up, and a plurality of interposer substrates 130 may be cut in the vertical direction (e.g., in the Z-direction) using the blade B to form the single interposer substrate 130.

Referring to FIG. 10F, the interposer substrate 130 may be mounted on the core structure 200, and the interposer substrate 130 may be fixed onto the core structure 200 using the underfill layer 180.

A core structure 200 including a core substrate 201 having a conductive via 203, interconnection structures 201a and 201b on the core substrate 201, a plurality of first to fourth build-up layers 210, 220, 230 and 240, and a plurality of passivation layers 250 may be provided. Specifically, the core structure 200 having an upper passivation layer 250a having an opening formed therein exposing at least portions of first and second interconnection patterns 209U1 and 209U2 of the uppermost layer may be provided.

The interposer substrate 130 may be mounted on the core structure 200 so that the connection bump 170 may come into contact with the first interconnection pattern 209U1 of the uppermost layer exposed by the opening, and the connection structure 175 may come into contact with the second interconnection pattern 209U2 of the uppermost layer exposed by the opening. Then, the underfill layer 180 filling the opening and surrounding the connection bump 170 may be formed, thereby fixing the interposer substrate 130 onto the core structure 200.

Accordingly, a semiconductor chip 140 including at least one first semiconductor chip 141 and at least one second semiconductor chip 142 may be formed on the first surface S1 of the redistribution substrate 120. The at least one first semiconductor chip 141 and the at least one second semiconductor chip 142 may be fixed onto the first surface S1 of the redistribution substrate 120 by the underfill resin 145. Referring to FIG. 5B together, the at least one first semiconductor chip 141 and the upper pad 110P2 of the rigid structure 110 may be electrically connected by the first redistribution pattern 122_1, the at least one first semiconductor chip 141 and the passive device 150 may be electrically connected by the second redistribution pattern 122_2, and the at least one first semiconductor chip 141 and the at least one second semiconductor chip 142 may be electrically connected by the third redistribution pattern 122_3.

Next, a plurality of open portions extending through the lower passivation layer 250b and exposing at least a portion of the interconnection pattern 209L of the lowermost layer may be formed. Then, an external connection terminal 300 may be formed on the interconnection pattern 209L of the lowermost layer exposed by the plurality of open portions, thereby forming the semiconductor package 1000B.

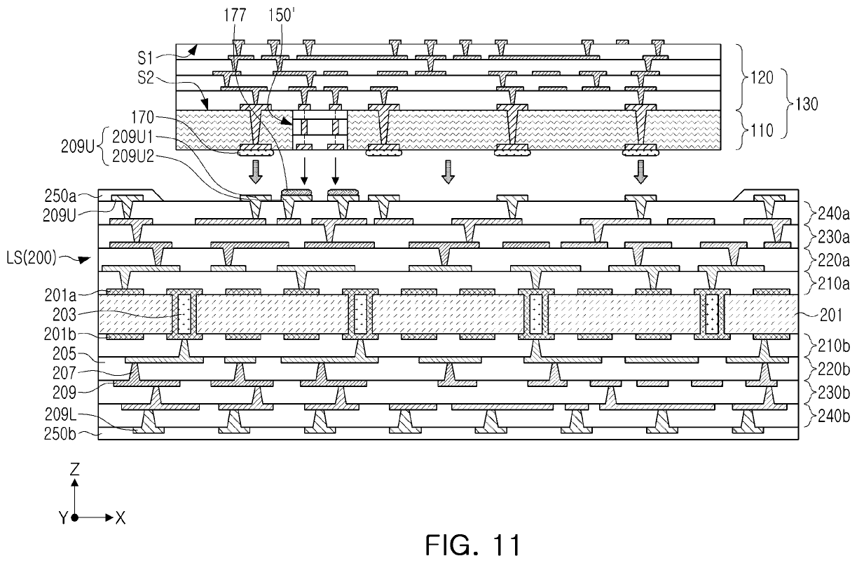

FIG. 11 is a cross-sectional view illustrating a method of manufacturing a semiconductor package according to some example implementations according to the process order. FIG. 11 may be a process diagram following FIG. 10E, and FIG. 11 may be a process diagram illustrating a method for manufacturing the semiconductor package 1000D illustrated in FIG. 8.

Referring to FIG. 11, an interposer substrate 130 may be mounted on a core structure 200.

Referring to FIG. 11, unlike FIG. 10E, a connection bump 175 may be formed only on a lower surface of a lower pad 110P1. From another perspective, a connection structure 175 (see FIG. 10E) may not be formed on a lower surface of the second connection terminal 152 of the passive device 150′.

A core structure 200 including a core substrate 201 having a conductive via 203, interconnection structures 201a and 201b on the core substrate 201, a plurality of first to fourth build-up layers 210, 220, 230 and 240, and a plurality of passivation layers 250 may be provided. Specifically, the core structure 200 having an upper passivation layer 250a having an opening formed therein exposing at least portions of first and second interconnection patterns 209U1 and 209U2 of the uppermost layer may be provided.

A connection structure 177 may be formed on the second interconnection patterns 209U2 of the uppermost layer of the core structure 200. The connection structure 177 may have different properties from the connection bump 170. The connection structure 177 may include, for example, a conductive paste. The connection structure 177 may include, for example, a polymer binder and fine metal particles dispersed in the polymer binder. The metal particles may include at least one of silver (Ag), copper (Cu), or gold (Au).

The interposer substrate 130 may be mounted on the core structure 200 so that the connection bump 170 may come into contact with the first interconnection pattern 209U1 of the uppermost layer exposed by the opening, and the connection structure 177 may come into contact with the second connection terminal 153 of the passive component 150′. Then, an underfill layer 180 (see FIG. 8) filling the opening and surrounding the connection bump 170 may be formed, thereby fixing the interposer substrate 130 on the core structure 200.

Then, a semiconductor chip 140 including at least one first semiconductor chip 141 and at least one second semiconductor chip 142 may be formed on the first surface S1 of the redistribution substrate 120. The at least one first semiconductor chip 141 and the at least one second semiconductor chip 142 may be fixed onto the first surface S1 of the redistribution substrate 120 by an underfill resin 145. Referring to FIG. 5B together, the at least one first semiconductor chip 141 and the upper pad 110P2 of the rigid structure 110 may be electrically connected by the first redistribution pattern 122_1, the at least one first semiconductor chip 141 and the passive device 150 may be electrically connected by the second redistribution pattern 122_2, and the at least one first semiconductor chip 141 and the at least one second semiconductor chip 142 may be electrically connected by the third redistribution pattern 122_3.

Next, a plurality of open portions extending through the lower passivation layer 250b and exposing at least a portion of the interconnection pattern 209L of the lowermost layer may be formed. Then, an external connection terminal 300 may be formed on the interconnection pattern 209L of the lowermost layer exposed by the plurality of open portions, thereby forming the semiconductor package 1000D.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The present disclosure is not limited to the above-described implementations and the accompanying drawings but is defined by the appended claims. Therefore, those of ordinary skill in the art may make various replacements, modifications, or changes, and combinations of example implementations without departing from the scope of the present disclosure defined by the appended claims, and these replacements, modifications, or changes should be construed as being included in the scope of the present disclosure.

What is claimed is:

1. A semiconductor package comprising:
a redistribution substrate having a first surface and a second surface opposite to the first surface, the redistribution substrate comprising:
a first insulating layer,
redistribution patterns on the first insulating layer and comprising first and second redistribution patterns, and
redistribution vias comprising a first redistribution via and a second redistribution via, the first redistribution via extending through the first insulating layer and being electrically connected to the first redistribution pattern, and the second redistribution via being electrically connected to the second redistribution pattern;
a semiconductor chip on the first surface of the redistribution substrate, the semiconductor chip being electrically connected to the redistribution patterns;
a rigid structure on the second surface of the redistribution substrate, the rigid structure having a through-hole,
wherein the rigid structure comprises:
a second insulating layer;
a lower pad at a lower portion of the second insulating layer;
an upper pad at an upper portion of the second insulating layer and electrically connected to the first redistribution via;
a through-via extending through the second insulating layer and connecting the lower pad and the upper pad; and
a passive device within the through-hole of the rigid structure, the passive device having a connection terminal in contact with the second redistribution via, and
wherein the first insulating layer and the second insulating layer comprise different insulating materials from each other.

2. The semiconductor package of claim 1,
wherein a rigidity of the insulating material of the second insulating layer is greater than a rigidity of the insulating material of the first insulating layer.

3. The semiconductor package of claim 1,
wherein the second insulating layer comprises an insulating film including an organic material.

4. The semiconductor package of claim 1,
wherein a thickness of the second insulating layer ranges from 60 μm to 100 μm.

5. The semiconductor package of claim 1,
wherein a largest diameter of the through-via in a horizontal direction ranges from 40 μm to 60 μm.

6. The semiconductor package of claim 1,
wherein the connection terminal of the passive device is on an active surface of the passive device,
wherein the active surface is in contact with a second surface of the redistribution substrate.

7. The semiconductor package of claim 1,
wherein the upper pad of the rigid structure and the connection terminal of the passive device are in the first insulating layer of the redistribution substrate.

8. The semiconductor package of claim 1,
wherein an upper surface of the upper pad of the rigid structure and an upper surface of the connection terminal of the passive device are on a same plane.

9. The semiconductor package of claim 1, further comprising:
a connection bump on a lower surface of the lower pad of the rigid structure,
wherein a thickness of the connection bump is a same as or smaller than a thickness of the lower pad.

10. The semiconductor package of claim 1, further comprising:
an adhesive layer in contact with a lower surface of the passive device,
wherein the lower surface of the adhesive layer is on a same plane as a lower surface of the second insulating layer of the rigid structure.

11. The semiconductor package of claim 1,
wherein a sidewall of the through-hole of the rigid structure is spaced apart from a side surface of the passive device.

12. The semiconductor package of claim 1,
wherein the passive device has a first active surface and a second active surface that is opposite to the first active surface, and
the connection terminal of the passive device is on the first active surface,
wherein the passive device further comprises:
an opposite connection terminal facing the connection terminal and disposed on the second active surface; and
a through-electrode electrically connecting the connection terminal and the opposite connection terminal.

13. The semiconductor package of claim 12,
wherein the second active surface of the passive device and a lower surface of the second insulating layer of the rigid structure are on a same plane.

14. The semiconductor package of claim 12, further comprising:
a connection bump on a lower surface of the lower pad of the rigid structure; and
a connection structure on a lower surface of the opposite connection terminal of the passive device,
wherein a largest width of the connection bump in a horizontal direction is greater than a largest width of the connection structure in the horizontal direction.

15. A semiconductor package, comprising:
a core structure comprising a core substrate and build-up layers stacked on each of an upper portion and a lower portion of the core substrate, the core structure having a first front pad on a front surface thereof;
an interposer substrate comprising:
a redistribution substrate on the core structure and having a first surface and a second surface opposite to the first surface, the redistribution substrate comprising a first insulating layer, redistribution patterns being on the first insulating layer and comprising first and second redistribution patterns, and redistribution vias comprising a first redistribution via extending through the first insulating layer and electrically connected to the first redistribution pattern and a second redistribution via electrically connected to the second redistribution pattern, and
a rigid structure on the second surface and having a through-hole, the rigid structure comprising a second insulating layer, a lower pad at a lower portion of the second insulating layer, an upper pad on an upper portion of the second insulating layer and electrically connected to the first redistribution pattern, and a through-via extending through the second insulating layer and connecting the lower and upper pads;
at least one first semiconductor chip on the first surface of the redistribution substrate, the at least one first semiconductor chip being electrically connected to the redistribution patterns;
a passive device within the through-hole of the rigid structure, and the passive device comprising a first active surface and a connection terminal on the first active surface and contacting the second redistribution via; and
a connection bump between the core structure and the rigid structure of the interposer substrate, the connection bump electrically connecting the first front pad of the core structure and a lower pad of the rigid structure,
wherein the first insulating layer and a second insulating layer comprise different insulating materials from each other.

16. The semiconductor package of claim 15,
wherein the passive device further comprises a second active surface opposite to the first active surface, and an opposite connection terminal facing the connection terminal and on the second active surface,
wherein the core structure further comprises a second front pad on the front surface, and
wherein the semiconductor package further comprises a connection structure between the core structure and the rigid structure of the interposer substrate, and electrically connecting the second front pad of the core structure and the opposite connection terminal of the passive device.

17. The semiconductor package of claim 16,
wherein the connection structure further comprises:
a first side facing a connection bump closest to the connection structure; and
a second side opposite to the first side, and
wherein a surface inclination of the first side based on an upper surface of the second front pad gradually becomes gentler as the first side approaches the second front pad.

18. The semiconductor package of claim 15,
wherein the redistribution patterns of the redistribution substrate further comprise a third redistribution pattern,
wherein the semiconductor package further comprises a second semiconductor chip on the first surface of the redistribution substrate and electrically connected to the at least one first semiconductor chip through the third redistribution pattern.

19. The semiconductor package of claim 18,
wherein the second semiconductor chip comprises a logic chip, and
wherein the at least one first semiconductor chip comprises a memory chip.

20. A semiconductor package, comprising:
a core structure comprising a core substrate and build-up layers stacked on an upper portion and a lower portion of the core substrate, the core structure having a front pad on a front surface thereof;
an interposer substrate comprising a redistribution substrate on the core structure and having a first surface and a second surface opposite to the first surface, and a rigid structure on the second surface and having a through-hole,
wherein the redistribution substrate comprises:
a first insulating layer;
redistribution patterns on the first insulating layer and including first, second, and third redistribution patterns; and
redistribution vias comprising a first redistribution via extending through the first insulating layer and being electrically connected to the first redistribution pattern and a second redistribution via electrically connected to the second redistribution pattern, and
wherein the rigid structure comprises:
a second insulating layer;
a lower pad at a lower portion of the second insulating layer;
an upper pad at an upper portion of the second insulating layer and electrically connected to the first redistribution pattern;
a through-via extending through the second insulating layer and connecting the lower pad and the upper pad;
at least one first semiconductor chip on the first surface of the redistribution substrate, the at least one first semiconductor chip being electrically connected to the first redistribution pattern and the second redistribution pattern;
a second semiconductor chip on the first surface of the redistribution substrate, the second semiconductor chip being electrically connected to the at least one first semiconductor chip by the third redistribution pattern;
a passive component within the through-hole of the rigid structure, the passive component being electrically connected to the at least one first semiconductor chip by the second redistribution pattern; and
a connection bump between the core structure and the rigid structure of the interposer substrate, the connection bump electrically connecting the front pad of the core structure and the lower pad of the rigid structure,
wherein the through-via and the passive component are in parallel with each other, and a width of the through-via in a horizontal direction becomes narrower as the through-via approaches the lower pad.
